(19) United States
(12) Patent Application Publication
(10) Pub. No.: US 2023/0125850 A1
(43) Pub. Date: Apr. 27, 2023

(54) FILM AND LAMINATE

(71) Applicant: FUJIFILM Corporation, Tokyo (JP)

(72) Inventor: Yasuyuki SASADA, Kanagawa (JP)

(73) Assignee: FUJIFILM Corporation, Tokyo (JP)

(21) Appl. No.: 17/896,015

(22) Filed: Aug. 25, 2022

(30) Foreign Application Priority Data
Aug. 30, 2021 (JP) 2021-140221

(51) Int. Cl. C08L 23/30; C09J 123/30; C09J 7/38; C09J 7/28

(52) U.S. Cl. CPC C08L 23/30; C09J 123/30; C09J 7/381; C09J 7/28; C08L 2205/03; C09J 2423/00; C09J 2400/163; H05K 1/0393

(57) ABSTRACT

Provided are a film including a matrix material, and a particle having an elastic modulus at 25° C. which is higher than an elastic modulus of the matrix material, in which the film has a region A at at least a part between the matrix material and the particle, and the region A contains a compound having a loss tangent of 0.1 or greater at 25° C.; and a laminate formed of the film.

### CROSS-REFERENCE TO RELATED APPLICATIONS

This application claims priority under 35 USC 119 from Japanese Patent Application No. 2021-140221 filed on Aug. 30, 2021, the disclosure of which is incorporated by reference herein in their entirety.

### BACKGROUND OF THE INVENTION

### 1. Field of the Invention

The present disclosure relates to a film and a laminate.

### 2. Description of the Related Art

In recent years, the frequencies used in communication equipment tend to be extremely high. In order to suppress transmission loss in a high frequency band, insulating materials used in circuit boards are required to have a lowered relative dielectric constant and a lowered dielectric loss tangent.

As a thermoplastic resin composition of the related art, for example, a thermoplastic resin composition described in JP2020-105415A has been known.

JP2020-105415A describes a thermoplastic resin composition containing a random copolymer that has two or more monomer units having different glass transition temperatures and formed of homopolymers, in which the composition has a structure in which components with different elastic moduli are phase-separated on a nanoscale during mapping of the elastic moduli using an atomic force microscope (AFM) in a case of being formed into a molding plate.

### SUMMARY OF THE INVENTION

An object to be achieved by an aspect of the present invention is to provide a film having improved brittleness.

Further, an object to be achieved by another aspect of the present invention is to provide a laminate formed of the film.

The means for achieving the above-described object includes the following aspects.

<1> A film comprising: a matrix material; and a particle having an elastic modulus at 25° C. which is higher than an elastic modulus of the matrix material, in which a region A is provided in at least a part between the matrix material and the particle, and the region A contains a compound having a loss tangent of 0.1 or greater at 25° C.

<2> The film according to <1>, in which an elastic modulus of the compound having a loss tangent of 0.1 or greater at 25° C. is 1 GPa or less.

<3> The film according to <1> or <2>, in which the particle is a particle having a surface on which a layer of the region A is provided.

<4> The film according to <3>, in which the layer of the region A has an average thickness of 0.01 μm to 10 μm.

<5> The film according to any one of <1> to <4>, in which a value of a ratio Ep/Em of an elastic modulus Ep of the particle at 25° C. to an elastic modulus Em of the matrix material at 25° C. is 1.2 or greater.

<6> The film according to any one of <1> to <5>, in which the particle is an inorganic particle.

<7> The film according to any one of <1> to <6>, in which a content of the particle is 10% by volume or greater with respect to a total volume of the film.

<8> The film according to any one of <1> to <7>, in which the matrix material has a dielectric loss tangent of 0.01 or less.

<9> The film according to any one of <1> to <8>, in which the matrix material contains at least one compound selected from the group consisting of a polymer and a monomer.

<10> The film according to any one of <1> to <9>, in which the matrix material contains at least one polymer selected from the group consisting of a liquid crystal polymer, a cycloolefin polymer, and a fluorine-based polymer.

<11> The film according to any one of <1> to <10>, in which the region A contains at least one selected from the group consisting of polyolefin and styrene-butadiene rubber.

<12> A laminate comprising: the film according to any one of <1> to <11>; and a copper layer or copper wire disposed on at least one surface of the film.

According to the aspect of the present invention, it is possible to provide a film having improved brittleness.

Further, according to another aspect of the present invention, it is possible to provide a laminate formed of the film.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

Further, in the present specification, a numerical range shown using “to” indicates a range including numerical values described before and after “to” as a lower limit and an upper limit.

In a numerical range described in a stepwise manner in the present disclosure, an upper limit or a lower limit described in one numerical range may be replaced with an upper limit or a lower limit in another numerical range described in a stepwise manner. Further, in a numerical range described in the present disclosure, an upper limit or a lower limit described in the numerical range may be replaced with a value described in an example.

Further, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

Further, the term “step” in the present specification indicates not only an independent step but also a step which cannot be clearly distinguished from other steps as long as the intended purpose of the step is achieved.

Further, in the present disclosure, “% by mass” has the same definition as that for “% by weight”, and “part by mass” has the same definition as that for “part by weight”.

Further, in the present disclosure, a combination of two or more preferred embodiments is a more preferred embodiment.

Further, the weight-average molecular weight (Mw) and the number average molecular weight (Mn) in the present disclosure are molecular weights converted using polystyrene as a standard substance by performing detection with a gel permeation chromatography (GPC) analyzer using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

Film

A film according to the present disclosure is a film including a matrix material, and a particle having an elastic modulus at 25° C. which is higher than the elastic modulus of the matrix material, in which a region A is provided in at least a part between the matrix material and the particle, and the region A contains a compound having a loss tangent of 0.1 or greater at 25° C.

Films containing particles of the related art have a problem that the brittleness is deteriorated.

Since the film according to the present disclosure has a region A containing a compound having a loss tangent of 0.1 or greater at 25° C., between a matrix material and a particle having an elastic modulus at 25° C. which is higher than the elastic modulus of the matrix material, the region A suppresses peeling due to the stress at the interface between the matrix material and the particle and suppresses concentration of the stress in voids generated in the peeled portion, and thus a film with improved brittleness can be provided.

The brittleness can be evaluated, for example, based on breaking elongation. It can be determined that the brittleness is improved as the breaking elongation increases.

Region A

The film according to the present disclosure has a region A in at least a part between the matrix material and the particle, and the region A contains a compound having a loss tangent of 0.1 or greater at 25° C.

The region A may be present in at least a part between the matrix material and the particle.

It is preferable that the region A is present to cover as larger area as possible on the surface of the particle. From the viewpoint of improving the brittleness, the region A is present at preferably 50 area % or greater, more preferably 65 area % or greater, and particularly preferably 80 area % or greater with respect to the total surface area of the particle.

Suitable examples of a method for forming the region A include a method of coating the surface of the particle with a compound having a loss tangent of 0.1 or greater at 25° C. and a method of forming a sea-island structure that has a sea structure formed of the matrix material and an island structure containing the particle and a compound having a loss tangent of 0.1 or greater at 25° C. Further, a method of forming a phase-separated structure of a phase containing the matrix material and a phase containing the particle and a compound having a loss tangent of 0.1 or greater at 25° C. is suitable.

Among these, from the viewpoint of improving the brittleness, it is preferable that a method of coating the surface of the particle with a compound having a loss tangent of 0.1 or greater at 25° C. is performed, that is, the particle is a particle having a surface on which a layer of the region A is provided.

From the viewpoint of improving the brittleness, the average thickness of the layer of the region A is preferably in a range of 0.01 μm to 10 μm, more preferably in a range of 0.1 μm to 5 μm, and particularly preferably in a range of 0.2 μm to 3 μm.

Further, in the method of forming a sea-island structure of an island structure containing the particle and a compound having a loss tangent of 0.1 or greater at 25° C., from the viewpoint of improving the brittleness, the average diameter of the island structure is preferably in a range of 0.01 μm to 10 μm, more preferably in a range of 0.1 μm to 5 μm, and particularly preferably in a range of 0.2 μm to 3 μm.

In a case of forming the sea-island structure, from the viewpoint of improving the brittleness, the average thickness of the region A between the matrix material and the particle is preferably in a range of 0.01 μm to 10 μm, more preferably in a range of 0.1 μm to 5 μm, and particularly preferably in a range of 0.2 μm to 3 μm.

The average thickness (of the layer) of the region A in the present disclosure is measured using the following method.

The thickness of the region A is evaluated by cutting the film with a microtome and observing the cross section with an optical microscope. Three or more sites of the cross-sectional sample are cut out, the thickness is measured at three or more points in each cross section, and the average value thereof is defined as the average thickness.

The compound having a loss tangent of 0.1 or greater at 25° C. is not particularly limited, and suitable examples thereof include a pressure sensitive adhesive, rubber, and a thermoplastic elastomer.

Examples of the pressure sensitive adhesive include an ethylene-vinyl acetate copolymer (EVA)-based pressure sensitive adhesive, an acrylic pressure sensitive adhesive, a rubber-based pressure sensitive adhesive, a polyolefin-based pressure sensitive adhesive (such as an acid-modified polyolefin pressure sensitive adhesive or a polyethylene oligomer pressure sensitive adhesive), a cellulose-based pressure sensitive adhesive (such as glue), a silicone-based pressure sensitive adhesive, a urethane-based pressure sensitive adhesive, a vinyl alkyl ether-based pressure sensitive adhesive, a polyvinyl alcohol-based pressure sensitive adhesive, a polyvinylpyrrolidone-based pressure sensitive adhesive, and a polyacrylamide-based pressure sensitive adhesive.

Among these, from the viewpoint of improving the brittleness, a polyolefin-based pressure sensitive adhesive is preferable, an acid-modified polyolefin-based pressure sensitive adhesive is more preferable, and an acid-modified polyolefin-based pressure sensitive adhesive containing an acid-modified polyolefin and an epoxy resin is particularly preferable as the pressure sensitive adhesive.

It is preferable that the acid-modified polyolefin is obtained by grafting at least one of an α,β-unsaturated carboxylic acid or an acid anhydride thereof onto a polyolefin. The polyolefin in the present disclosure denotes a polymer mainly having a hydrocarbon skeleton, such as a homopolymer of an olefin monomer such as ethylene, propylene, butene, butadiene, or isoprene, a copolymer with other monomers, or a hydride or a halide of the obtained polymer. That is, it is preferable that the acid-modified polyolefin is obtained by grafting at least one of an α,β-unsaturated carboxylic acid or an acid anhydride thereof onto at least one of polyethylene, polypropylene, or a propylene-α-olefin copolymer.

The propylene-α-olefin copolymer is obtained by copolymerizing α-olefin mainly with propylene. As the α-olefin, for example, one or a plurality of kinds from among ethylene, 1-butene, 1-heptene, 1-octene, 4-methyl-1-pentene, and vinyl acetate. Among these α-olefins, ethylene and 1-butene are preferable. The ratio of the propylene component to the content of the α-olefin component of the propylene-α-olefin copolymer is not limited, but the content of the propylene component is preferably 50% by mole or greater and more preferably 70% by mole or greater.

Examples of at least one of an α,β-unsaturated carboxylic acid or an acid anhydride thereof include maleic acid, itaconic acid, citraconic acid, and acid anhydrides thereof. Among these, an acid anhydride is preferable, and maleic acid anhydride is more preferable. Specific examples thereof include maleic acid anhydride-modified polypropylene, a maleic acid anhydride-modified propylene-ethylene copolymer, a maleic acid anhydride-modified propylene-butene copolymer, and a maleic acid anhydride-modified propylene-ethylene-butene copolymer, and one or two or more kinds of these acid-modified polyolefins can be used in combination.

The epoxy resin is not particularly limited as long as the epoxy resin contains an epoxy group in a molecule, but it is preferable that the epoxy resin contains two or more glycidyl groups in a molecule. Specifically, although not particularly limited, at least one selected from the group consisting of a biphenyl type epoxy resin, a naphthalene type epoxy resin, a bisphenol A type epoxy resin, a bisphenol F type epoxy resin, a novolak type epoxy resin, an alicyclic epoxy resin, a dicyclopentadiene type epoxy resin, tetraglycidyl diaminodiphenylmethane, triglycidyl paraaminophenol, tetraglycidyl bisaminomethyl cyclohexanone, N,N,N′,N′-tetraglycidyl-m-xylenediamine, and epoxy-modified polybutadiene can be used. Among these, a biphenyl type epoxy resin, a novolak type epoxy resin, a dicyclopentadiene type epoxy resin, or epoxy-modified polybutadiene is preferable, and a dicyclopentadiene type epoxy resin is more preferable.

The content of the epoxy resin in the polyolefin-based pressure sensitive adhesive is preferably 0.5 parts by mass or greater, more preferably 1 part by mass or greater, still more preferably 5 parts by mass or greater, and particularly preferably 10 parts by mass or greater with respect to 100 parts by mass of the acid-modified polyolefin. Further, the upper limit of the content is preferably 60 parts by mass or less, more preferably 50 parts by mass or less, still more preferably 40 parts by mass or less, and particularly preferably 35 parts by mass or less.

Further, as the polyolefin-based pressure sensitive adhesive, those described in WO2021/075367A can be suitably used.

Examples of the rubber include chemically synthesized synthetic rubber such as styrene-butadiene rubber, acrylonitrile-butadiene rubber, butadiene rubber, isoprene rubber, chloroprene rubber, ethylene-propylene rubber, ethylene-propylene-diene copolymerized rubber (EPDM), ethylene-butene rubber, ethylene-octene rubber, butyl rubber, acrylic rubber, silicone rubber, or chlorinated polyethylene, and natural rubber.

Examples of the thermoplastic elastomer include a urethane-based thermoplastic elastomer, an ester-based thermoplastic elastomer, an amide-based thermoplastic elastomer, and a silicone-based thermoplastic elastomer.

Among these, from the viewpoint of improving the brittleness, styrene-butadiene rubber is preferable as the rubber and the thermoplastic elastomer.

From the viewpoint of improving the brittleness, the compound having a loss tangent of 0.1 or greater at 25° C. contains preferably at least one selected from the group consisting of a polyolefin and styrene-butadiene rubber, more preferably a polyolefin, and particularly preferably an acid-modified polyolefin.

From the viewpoint of improving the brittleness, the elastic modulus of the compound at 25° C. which has a loss tangent of 0.1 or greater at 25° C. is preferably 2 GPa or less, more preferably 1 GPa or less, and particularly preferably 0.5 GPa or less.

From the viewpoint of improving the brittleness, the loss tangent of the compound having a loss tangent of 0.1 or greater at 25° C. is preferably 0.1 or greater and 2 or less, more preferably 0.15 or greater and 1.5 or less, still more preferably 0.2 or greater and 1.2 or less, and particularly preferably 0.25 or greater and 1.2 or less.

The elastic modulus of each component in the present disclosure (referred to as the storage elastic modulus in the present disclosure) and the loss tangent are measured by the following method.

A sample for evaluating a cross section is prepared by embedding a film in an ultraviolet curable resin (UV resin) and cutting the film with a microtome. Subsequently, the storage elastic modulus and the loss tangent (loss elastic modulus/storage elastic modulus) of each component at a measurement temperature are calculated by observing the sample in a VE-AFM mode using a scanning probe microscope (SPA400, manufactured by Hitachi High-Tech Science Corporation).

The compound having a loss tangent of 0.1 or greater at 25° C. may be used alone or in combination of two or more kinds thereof.

Further, from the viewpoint of improving brittleness, the content of the compound having a loss tangent of 0.1 or greater at 25° C. is preferably in a range of 0.1% by mass to 30% by mass, more preferably in a range of 0.3% by mass to 20% by mass, and particularly preferably in a range of 0.5% by mass to 10% by mass with respect to the total mass of the film.

### Particles

The film according to the present disclosure contains particles having an elastic modulus at 25° C. which is higher than the elastic modulus of the matrix material.

The elastic modulus of the particles is not limited as long as the elastic modulus thereof is higher than that of the matrix material, but from the viewpoint of improving the brittleness, the elastic modulus of the particles at 25° C. is preferably 5 GPa or greater, more preferably 8 GPa or greater, and particularly preferably 10 GPa or greater.

From the viewpoint of further exhibiting the effects of the present disclosure, the value of a ratio Ep/Em of an elastic modulus Ep of the particles at 25° C. to an elastic modulus Em of the matrix material at 25° C. is preferably 1.2 or greater, more preferably 1.5 or greater, still more preferably 2.0 or greater, and particularly preferably 3.0 or greater.

The particles may be inorganic particles or organic particles, but are preferably inorganic particles from the viewpoint of further exhibiting the effects in the present disclosure.

In a case where the particles are inorganic particles, examples of the material of the particles include BN, Al₂O₃, AlN, TIO₂, SiO₂, barium titanate, strontium titanate, aluminum hydroxide, calcium carbonate, and materials containing two or more kinds thereof.

Among these, from the viewpoint of improving the brittleness, metal oxide particles or boron nitride (BN) particles are preferable, and silica particles are more preferable as the inorganic particles.

Further, in a case where the particles are organic particles, a polymer is preferable, and a thermoplastic resin is more preferable as the material of the particles.

Examples of the polymer include thermoplastic resins such as a liquid crystal polymer, a fluororesin, a polymerized substance of a compound containing a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide, elastomers such as a copolymer of glycidyl methacrylate and polyethylene, and thermosetting resins such as a phenol resin, an epoxy resin, a polyimide resin, and a cyanate resin.

From the viewpoint of improving the brittleness, the average particle diameter of the particles is preferably in a range of 5 nm to 5 μm, more preferably in a range of 10 nm to 2 μm, still more preferably in a range of 20 nm to 1 μm, and particularly preferably 25 nm to 500 nm. Further, the average particle diameter in the present disclosure denotes a 50% volume average diameter (D50; also referred to as a medium particle diameter).

The film according to the present disclosure may contain only one or two or more kinds of the particles.

From the viewpoint of improving the brittleness, the content of the particles in the film according to the present disclosure is preferably 10% by volume or greater, more preferably in a range of 15% by volume to 70% by volume, and particularly preferably in a range of 20% by volume to 65% by volume with respect to the total volume of the film.

Further, from the viewpoint of improving the brittleness, the total content of the particles and the compound having a loss tangent of 0.1 or greater at 25° C. in the film according to the present disclosure is preferably 20% by volume or greater, more preferably in a range of 20% by volume to 80% by volume, and particularly preferably in a range of 25% by volume to 70% by volume with respect to the total volume of the film.

Matrix Material

The film according to the present disclosure contains a matrix material.

The matrix material is not particularly limited as long as the elastic modulus of the matrix material at 25° C. is less than the elastic modulus of the particles, but from the viewpoint of improving the brittleness, the matrix material contains preferably at least one compound selected from the group consisting of polymers and monomers, more preferably a polymer, still more preferably at least one polymer selected from the group consisting of a liquid crystal polymer, a cycloolefin polymer, and a fluorine-based polymer, and particularly preferably a liquid crystal polymer.

From the viewpoints of the dielectric loss tangent of the film and the adhesiveness to the metal foil or the metal wire, the dielectric loss tangent of the matrix material is preferably 0.01 or less, more preferably 0.005 or less, still more preferably 0.004 or less, and particularly preferably greater than 0 and 0.003 or less.

The method of measuring the dielectric loss tangent of the film, the particle, or the matrix material in the present disclosure is as follows.

The dielectric loss tangent is measured by the resonance perturbation method at a frequency of 10 GHz. A 10 GHz cavity resonator (CP531, manufactured by EM labs, Inc.) is connected to a network analyzer (“E8363B”, manufactured by Agilent Technology), and a film or polymer sample (width: 2.0 mm×length: 80 mm) is inserted into the cavity resonator, and the dielectric loss tangent of the film or the polymer is measured based on a change in resonance frequency before and after the insertion in an environment of a temperature of 25° C. and a humidity 60% RH for 96 hours. Further, in a case of a laminate having a metal foil, the metal foil is removed by ferric chloride before the measurement.

Further, the dielectric loss tangent of the particles is measured by the above-described method after preparing a green compact sample (width: 2.0 mm×length: 80 mm) by compression molding.

The monomer is not particularly limited and may be a polymerizable monomer or a polycondensable monomer, and known monomers can be used.

Further, in a case where the above-described monomer is used, it is preferable to use a monomer having a high viscosity or to use a combination of the polymer and the monomer described above from the viewpoint of film forming properties.

As the monomer, an ethylenically unsaturated compound is preferable and a polyfunctional ethylenic compound is more preferable.

Examples of the ethylenically unsaturated compound include a (meth) acrylate compound, a (meth)acrylamide compound, a (meth)acrylic acid, a styrene compound, a vinyl acetate compound, a vinyl ether compound, and an olefin compound.

Among these, a (meth)acrylate compound is preferable.

From the viewpoint of the adhesiveness of the film to the metal foil or metal wire, the molecular weight of the monomer is preferably 50 or greater and less than 1,000, more preferably 100 or greater and less than 1,000, and particularly preferably 200 or greater and 800 or less.

In a case where the matrix material contains a monomer, it is preferable that the film according to the present disclosure contains a polymerization initiator. As the polymerization initiator, a thermal polymerization initiator or a photopolymerization initiator is preferable.

As the thermal polymerization initiator or the photopolymerization initiator, known polymerization initiators can be used.

Examples of the thermal polymerization initiator include a thermal radical generator. Specific examples thereof include a peroxide initiator such as benzoyl peroxide or azobisisobutyronitrile, and an azo-based initiator.

Examples of the photopolymerization initiator include a photoradical generator. Specific examples thereof include (a) aromatic ketones, (b) onium salt compounds, (c) organic peroxides, (d) thio compounds, (e) hexaarylbiimidazole compounds, (f) ketooxime ester compounds, (g) borate compounds, (h) azinium compounds, (i) active ester compounds, (j) compounds having a carbon halogen bond, and (k) pyridium compounds.

The polymerization initiator may be added alone or in combination of two or more kinds thereof.

The content of the polymerization initiator is preferably in a range of 0.01% by mass to 30% by mass, more preferably in a range of 0.05% by mass to 25% by mass, and still more preferably in a range of 0.1% by mass to 20% by mass with respect to the total mass of the monomer.

The kind of the polymer is not particularly limited, and a known polymer can be used.

Examples of the polymer include thermoplastic resins such as a liquid crystal polymer, a fluoropolymer, a polymerized substance of a compound containing a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide, elastomers such as a copolymer of glycidyl methacrylate and polyethylene, and thermosetting resins such as a phenol resin, an epoxy resin, a polyimide resin, and a cyanate resin.

Liquid Crystal Polymer

From the viewpoint of the dielectric loss tangent of the film, it is preferable that the polymer is a liquid crystal polymer.

Further, the liquid crystal polymer may be a thermotropic liquid crystal polymer that exhibits liquid crystallinity in a melting state or may be a lyotropic liquid crystal polymer that exhibits liquid crystallinity in a solution state. Further, in a case of the thermotropic liquid crystal polymer, it is preferable that the polymer is melted at a temperature of 450° C. or lower.

Examples of the liquid crystal polymer include liquid crystal polyester, liquid crystal polyester amide in which an amide bond is introduced into liquid crystal polyester, liquid crystal polyester ether in which an ether bond is introduced into liquid crystal polyester, and liquid crystal polyester carbonate in which a carbonate bond is introduced into liquid crystal polyester.

Further, from the viewpoint of the liquid crystallinity and the linear expansion coefficient, a polymer having an aromatic ring is preferable, and aromatic polyester or aromatic polyester amide is more preferable as the liquid crystal polymer.

Further, the liquid crystal polymer may be a polymer in which an imide bond, a carbodiimide bond, a bond derived from an isocyanate such as an isocyanurate bond, or the like is further introduced into aromatic polyester or aromatic polyester amide.

Further, it is preferable that the liquid crystal polymer is a wholly aromatic liquid crystal polymer formed of only an aromatic compound as a raw material monomer.

Examples of the liquid crystal polymer include

1) a liquid crystal polymer obtained by polycondensing an aromatic hydroxycarboxylic acid (i), an aromatic dicarboxylic acid (ii), and at least one compound (iii) selected from the group consisting of an aromatic diol, an aromatic hydroxyamine and an aromatic diamine,

2) a liquid crystal polymer obtained by polycondensing a plurality of kinds of aromatic hydroxycarboxylic acids,

3) a liquid crystal polymer obtained by polycondensing an aromatic dicarboxylic acid (i) and at least one compound (ii) selected from the group consisting of an aromatic diol, an aromatic hydroxyamine, and an aromatic diamine, and

4) a liquid crystal polymer obtained by polycondensing polyester (i) such as polyethylene terephthalate and an aromatic hydroxycarboxylic acid (ii).

Here, as a part or the entirety of the aromatic hydroxycarboxylic acid, the aromatic dicarboxylic acid, the aromatic diol, the aromatic hydroxyamine, and the aromatic diamine, each independently, a derivative that can be polycondensed may be used.

Examples of the polymerizable derivative of a compound containing a carboxy group, such as an aromatic hydroxycarboxylic acid or an aromatic dicarboxylic acid, include a derivative (ester) obtained by converting a carboxy group to an alkoxycarbonyl group or an aryloxycarbonyl group, a derivative (acid halide) obtained by converting a carboxy group to a haloformyl group, and a derivative (acid anhydride) obtained by converting a carboxy group to an acyloxycarbonyl group.

Examples of the polymerizable derivative of a compound containing a hydroxy group, such as an aromatic hydroxycarboxylic acid, an aromatic diol, or an aromatic hydroxyamine, include a derivative (acylated product) obtained by acylating a hydroxy group and converting the acylated group to an acyloxy group.

Examples of the polymerizable derivative of a compound containing an amino group, such as an aromatic hydroxyamine or an aromatic diamine, include a derivative (acylated product) obtained by acylating an amino group and converting the acylated group to an acylamino group.

From the viewpoints of the liquid crystallinity, the dielectric loss tangent of the film, and the adhesiveness to the metal foil or the metal wire, the liquid crystal polymer has preferably a constitutional repeating unit represented by any of Formulae (1) to (3) (hereinafter, the constitutional repeating unit and the like represented by Formula (1) will also be referred to as the repeating unit (1) and the like), more preferably a constitutional repeating unit represented by Formula (1), and particularly preferably a constitutional repeating unit represented by Formula (1), a constitutional repeating unit represented by Formula (2), and a constitutional repeating unit represented by Formula (3).

—O—Ar¹—CO— Formula (1)

—CO—Ar²—CO— Formula (2)

—X—Ar³—Y— Formula (3)

In Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in the groups represented by Ar¹ to Ar³ may be each independently substituted with a halogen atom, an alkyl group, or an aryl group.

—Ar⁴—Z—Ar⁵— Formula (4)

In Formula (4), Ar⁴ and Ar⁵ each independently represent a phenylene group or a naphthylene group, and Z represents an oxygen atom, a sulfur atom, a carbonyl group, a sulfonyl group, or an alkylene group.

Examples of the halogen atom of include a fluorine atom, a chlorine atom, a bromine atom, and an iodine atom.

Examples of the alkyl group include a methyl group, an ethyl group, an n-propyl group, an isopropyl group, an n-butyl group, an isobutyl group, an s-butyl group, a t-butyl group, an n-hexyl group, a 2-ethylhexyl group, an n-octyl group, and an n-decyl group, and the number of carbon atoms thereof is preferably in a range of 1 to 10.

Examples of the aryl group include a phenyl group, an o-tolyl group, an m-tolyl group, a p-tolyl group, a 1-naphthyl group, and a 2-naphthyl group, and the number of carbon atoms is preferably in a range of 6 to 20.

In a case where the hydrogen atom is substituted with any of these groups, the number thereof is preferably 2 or less and more preferably 1 for each group independently represented by Ar¹, Ar², or Ar³.

Examples of the alkylene group include a methylene group, a 1,1-ethanediyl group, a 1-methyl-1,1-ethanediyl group, a 1,1-butanediyl group, and a 2-ethyl-1,1-hexanediyl group, and the number of carbon atoms thereof is preferably in a range of 1 to 10.

The repeating unit (1) is a constitutional repeating unit derived from a predetermined aromatic hydroxycarboxylic acid.

Preferred examples of the repeating unit (1) include a constitutional repeating unit in which Ar¹ represents a p-phenylene group (constitutional repeating unit derived from p-hydroxybenzoic acid), a constitutional repeating unit in which Ar¹ represents a 2,6-naphthylene group (constitutional repeating unit derived from 6-hydroxy-2-naphthoic acid), and a constitutional repeating unit in which Ar¹ represents a 4,4′-biphenylylene group (constitutional repeating unit derived from 4′-hydroxy-4-biphenylcarboxylic acid).

The repeating unit (2) is a constitutional repeating unit derived from a predetermined aromatic dicarboxylic acid.

Preferred examples of the repeating unit (2) include a constitutional repeating unit in which Ar² represents a p-phenylene group (constitutional repeating unit derived from terephthalic acid), a constitutional repeating unit in which Ar² represents an m-phenylene group (constitutional repeating unit derived from isophthalic acid), a constitutional repeating unit in which Ar² represents a 2,6-naphthylene group (constitutional repeating unit derived from 2,6-naphthalenedicarboxylic acid), and a constitutional repeating unit in which Ar² represents a diphenylether-4,4′-diyl group (constitutional repeating unit derived from diphenylether-4,4′-dicarboxylic acid).

The repeating unit (3) is a constitutional repeating unit derived from a predetermined aromatic diol, an aromatic hydroxylamine, or an aromatic diamine.

Preferred examples of the repeating unit (3) include a constitutional repeating unit in which Ar³ represents a p-phenylene group (constitutional repeating unit derived from hydroquinone, p-aminophenol, or p-phenylenediamine), a constitutional repeating unit in which Ar³ represents an m-phenylene group (constitutional repeating unit derived from isophthalic acid), and a constitutional repeating unit in which Ar³ represents a 4,4′-biphenylylene group (constitutional repeating unit derived from 4,4′-dihydroxybiphenyl, 4-amino-4′-hydroxybiphenyl, or 4,4′-diaminobiphenyl).

The content of the repeating unit (1) is preferably 30% by mole or greater, more preferably in a range of 30% by mole to 80% by mole, still more preferably in a range of 30% by mole to 60% by mole, and particularly preferably in a range of 30% by mole to 40% by mole with respect to the total amount of all constitutional repeating units (value obtained by dividing the mass of each constitutional repeating unit constituting the liquid crystal polymer by the formula weight of each repeating unit to acquire the amount (mole) equivalent to the substance amount of each repeating unit and adding up the acquired values).

The content of the repeating unit (2) is preferably 35% by mole or less, more preferably in a range of 10% by mole to 35% by mole, still more preferably in a range of 20% by mole to 35% by mole, and particularly preferably in a range of 30% by mole to 35% by mole with respect to the total amount of all constitutional repeating units.

The content of the repeating unit (3) is preferably 35% by mole or less, more preferably in a range of 10% by mole to 35% by mole, still more preferably in a range of 20% by mole to 35% by mole, and particularly preferably in a range of 30% by mole to 35% by mole with respect to the total amount of all constitutional repeating units.

The heat resistance, the strength, and the rigidity are likely to be improved as the content of the repeating unit (1) increases, but the solubility in a solvent is likely to be decreased in a case where the content thereof is extremely large.

The ratio of the content of the repeating unit (2) to the content of the repeating unit (3) is expressed as [content of repeating unit (2)]/[content of repeating unit (3)] (mol/mol) and is preferably in a range of 0.9/1 to 1/0.9, more preferably in a range of 0.95/1 to 1/0.95, and still more preferably in a range of 0.98/1 to 1/0.98.

The liquid crystal polymer may have two or more kinds of each of the repeating units (1) to (3) independently. Further, the liquid crystal polymer may have a constitutional repeating unit other than the repeating units (1) to (3), but the content thereof is preferably 10% by mole or less and more preferably 5% by mole or less with respect to the total amount of all the repeating units.

The liquid crystal polymer has preferably a repeating unit in which at least one of X or Y represents an imino group, that is, at least one of a constitutional repeating unit derived from a predetermined aromatic hydroxylamine or a constitutional repeating unit derived from an aromatic diamine as the repeating unit (3) from the viewpoint of excellent solubility in a solvent and more preferably only a repeating unit in which at least one of X or Y represents an imino group as the repeating unit (3).

It is preferable that the liquid crystal polymer is produced by melt-polymerizing raw material monomers corresponding to the constitutional repeating units constituting the liquid crystal polymer. The melt polymerization may be carried out in the presence of a catalyst, and examples of the catalyst include metal compounds such as magnesium acetate, stannous acetate, tetrabutyl titanate, lead acetate, sodium acetate, potassium acetate, and antimony trioxide, and nitrogen-containing heterocyclic compounds such as 4-(dimethylamino)pyridine and 1-methylimidazole. Among these, the nitrogen-containing heterocyclic compounds are preferably used. The melt polymerization may be further carried out by solid phase polymerization as necessary.

The flow start temperature of the liquid crystal polymer is preferably 250° C. or higher, more preferably 250° C. or higher and 350° C. or lower, and still more preferably 260° C. or higher and 330° C. or lower. In a case where the flow start temperature of the liquid crystal polymer is in the above-described range, the solubility, the heat resistance, the strength, and the rigidity are excellent, and the viscosity of the solution is appropriate.

The flow start temperature, also referred to as a flow temperature, is a temperature at which a viscosity of 4,800 Pas (48,000 poises) is exhibited in a case where the liquid crystal polymer is melted and extruded from a nozzle having an inner diameter of 1 mm and a length of 10 mm while the temperature is raised at a rate of 4° C./min under a load of 9.8 MPa (100 kg/cm²) using a capillary rheometer and is a guideline for the molecular weight of liquid crystal polyester (“Liquid Crystal Polymers—Synthesis/Molding/Applications—”, written by Naoyuki Koide, CMC Corporation, Jun. 5, 1987, see p. 95).

Further, the weight-average molecular weight of the liquid crystal polymer is preferably 1,000,000 or less, more preferably 3,000 to 300,000, still more preferably in a range of 5,000 to 100,000, and particularly preferably in a range of 5,000 to 30,000. In a case where the weight-average molecular weight of the liquid crystal polymer is in the above-described range, the film after heat treatment is excellent in thermal conductivity, heat resistance, strength, and rigidity in the thickness direction.

Cycloolefin Polymer

Examples of the cycloolefin polymer include a norbornene-based polymer, a monocyclic cyclic olefin polymer, a cyclic conjugated diene polymer, a vinyl alicyclic hydrocarbon polymer, and hydrides of these polymers.

Further, examples of the ring structure in the cycloolefin polymer include a cyclopentane ring, a cyclohexane ring, a cyclooctane ring, an isophorone ring, a norbornane ring, and a dicyclopentane ring.

Fluorine-Based Polymer

From the viewpoints of the heat resistance and the mechanical strength, a fluorine-based polymer is preferable as the polymer.

In the present disclosure, the kind of the fluorine-based polymer used as the polymer is not particularly limited as long as the dielectric loss tangent thereof is 0.01 or less, and a known fluorine-based polymer can be used.

Examples of the fluorine-based polymer include polytetrafluoroethylene, polychlorotrifluoroethylene, polyvinylidene fluoride, polyvinyl fluoride, a perfluoroalkoxy fluororesin, an ethylene tetrafluoride/propylene hexafluoride copolymer, an ethylene/ethylene tetrafluoride copolymer, and an ethylene/chlorotrifluoroethylene copolymer.

Among these, polytetrafluoroethylene is preferable.

The weight-average molecular weight Mw of the polymer is preferably 1,000 or greater, more preferably 2,000 or greater, and particularly preferably 5,000 or greater. Further, the weight-average molecular weight Mw of the polymer having a dielectric loss tangent of 0.005 or less is preferably 1,000,000 or less, more preferably 300,000 or less, and particularly preferably less than 100,000.

From the viewpoints of the dielectric loss tangent of the film, the adhesiveness to the metal foil or the metal wire, and the heat resistance, the melting point Tm of the polymer is preferably 200° C. or higher, more preferably 250° C. or higher, still more preferably 280° C. or higher, and particularly preferably 300° C. or higher and 420° C. or lower.

The melting point Tm in the present disclosure is defined as a value measured by a differential scanning calorimetry (DSC) device.

From the viewpoints of the dielectric loss tangent of the film, the adhesiveness to the metal foil or the metal wire, and the heat resistance, the glass transition temperature Tg of the polymer is preferably 150° C. or higher, more preferably 200° C. or higher, and particularly preferably 200° C. or higher and lower than 280° C.

The glass transition temperature Tg in the present disclosure is defined as a value measured by a differential scanning calorimetry (DSC) device.

The polymer film according to the present disclosure may contain only one or two or more kinds of the matrix materials.

From the viewpoint of improving the brittleness, the content of the matrix material in the film according to the present disclosure is preferably in a range of 20% by volume to 90% by volume, more preferably in a range of 25% by volume to 80% by volume, and particularly preferably in a range of 30% by volume to 70% by volume with respect to the total volume of the film.

Other Additives

The film according to the present disclosure may contain other additives.

Known additives can be used as other additives. Specific examples of other additives include a leveling agent, an antifoaming agent, an antioxidant, an ultraviolet absorbing agent, a flame retardant, and a colorant.

The total content of the other additives is preferably 25 parts by mass or less, more preferably 10 parts by mass or less, and still more preferably 5 parts by mass or less with respect to 100 parts by mass of the content of the matrix material.

Dielectric Loss Tangent

From the viewpoint of suppressing breakage failure during peeling and reducing the transmission loss of the prepared substrate, the dielectric loss tangent of the film according to the present disclosure is preferably 0.01 or less, more preferably 0.005 or less, still more preferably 0.004 or less, and particularly preferably greater than 0 and 0.003 or less.

Thermal Expansion Coefficient

From the viewpoint of thermal stability, the thermal expansion coefficient of the film according to the present disclosure is preferably in a range of −20 ppm/K to 50 ppm/K, more preferably in a range of −10 ppm/K to 40 ppm/K, still more preferably in a range of 0 ppm/K to 35 ppm/K, and particularly preferably in a range of 10 ppm/K to 30 ppm/K.

The thermal expansion coefficient in the present disclosure is measured by the following method.

A tensile load of 1 g is applied to both ends of a film having a width of 5 mm and a length of 20 mm, and the thermal expansion coefficient is calculated from the inclination of the TMA curve between 30° C. and 150° C. using a thermomechanical analyzer (TMA) in a case where the temperature is raised from 25° C. to 200° C. at a rate of 5° C./min, lowered to 30° C. at a rate of 2° C./min, and raised again at a rate of 5° C./min. Further, the copper foil is removed with ferric chloride before the measurement.

The film according to the present disclosure may have a monolayer structure or a multilayer structure.

For example, the film according to the present disclosure may have a structure having a layer A that contains the matrix material, the particles, a compound having a loss tangent of 0.1 or greater at 25° C., and the region A, and a layer B provided on at least one surface of the layer A or a structure having a layer B, a layer A that contains the matrix material, the particles, a compound having a loss tangent of 0.1 or greater at 25° C., and the region A, and a layer C in this order.

Further, it is preferable that the layer B and the layer C each independently contain a liquid crystal polymer.

The average thickness of the layer A is not particularly limited, but from the viewpoints of the dielectric loss tangent of the film and the adhesiveness to the metal foil or the metal wire, the average thickness thereof is preferably in a range of 5 μm to 90 μm, more preferably in a range of 10 μm to 70 μm, and particularly preferably in a range of 15 μm to 50 μm.

A method of measuring the average thickness of each layer in the film according to the present disclosure is as follows.

The thickness of each layer is evaluated by cutting the film with a microtome and observing the cross section with an optical microscope. Three or more sites of the cross-sectional sample are cut out, the thickness is measured at three or more points in each cross section, and the average value thereof is defined as the average thickness.

From the viewpoints of the dielectric loss tangent of the film and the adhesiveness to the metal foil or the metal wire, it is preferable that the average thicknesses of the layer B and the layer C are each independently less than the average thickness of the layer A.

From the viewpoints of the dielectric loss tangent of the film and the adhesiveness to the metal foil or the metal wire, the value of T^{A}/T^{B}, which is the ratio of an average thickness T^{A} of the layer A to an average thickness T^{B} of the layer B, is preferably greater than 1, more preferably in a range of 2 to 100, still more preferably in a range of 2.5 to 20, and particularly preferably in a range of 3 to 10.

From the viewpoints of the dielectric loss tangent of the film and the adhesiveness to the metal foil or the metal wire, the value of T^{A}/T^{C}, which is the ratio of the average thickness T^{A} of the layer A to an average thickness T^{C} of the layer C, is preferably greater than 1, more preferably in a range of 2 to 100, still more preferably in a range of 2.5 to 20, and particularly preferably in a range of 3 to 10.

Further, from the viewpoints of the linear expansion coefficient and the adhesiveness to the metal foil or the metal wire, the value of T^{C}/T^{B}, which is the ratio of the average thickness T^{C} of the layer C to the average thickness T^{B} of the layer B, is preferably in a range of 0.2 to 5, more preferably in a range of 0.5 to 2, and particularly preferably in a range of 0.8 to 1.2.

Further, from the viewpoints of the dielectric loss tangent of the film and the adhesiveness to the metal foil or the metal wire, the average thicknesses of the layer B and the layer C are each independently preferably in a range of 0.1 μm to 20 μm, more preferably in a range of 0.5 μm to 15 μm, still more preferably in a range of 1 μm to 10 μm, and particularly preferably in a range of 3 μm to 8 μm.

From the viewpoints of the strength, the thermal expansion coefficient, and the adhesiveness to the metal foil or the metal wire, the average thickness of the film according to the present disclosure is preferably in a range of 6 μm to 200 μm, more preferably in a range of 12 μm to 100 μm, and particularly preferably in a range of 20 μm to 60 μm.

The average thickness of the film is measured at optional five sites using an adhesive film thickness meter, for example, an electronic micrometer (product name, “KG3001A”, manufactured by Anritsu Corporation), and the average value of the measured values is defined as the average thickness of the film.

Applications

The film according to the present disclosure can be used for various applications. Among the various applications, the film can be used suitably as a film for an electronic component such as a printed wiring board and more suitably for a flexible printed circuit board.

Further, the film according to the present disclosure can be suitably used as a metal adhesive film.

Method of Producing Film

Film Formation

A method of producing the film according to the present disclosure is not particularly limited, and a known method can be referred to.

Suitable examples of the method of producing the film according to the present disclosure include a co-casting method, a multilayer coating method, and a co-extrusion method. Among these, the co-casting method is particularly preferable for formation of a relatively thin film, and the co-extrusion method is particularly preferable for formation of a thick film.

In a case where the film is produced by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer such as the liquid crystal polymer in each solvent.

Examples of the solvent include a halogenated hydrocarbon such as dichloromethane, chloroform, 1,1-dichloroethane, 1,2-dichloroethane, 1,1,2,2-tetrachloroethane, 1-chlorobutane, chlorobenzene, or o-dichlorobenzene, a halogenated phenol such as p-chlorophenol, pentachlorophenol, or pentafluorophenol, an ether such as diethyl ether, tetrahydrofuran, or 1,4-dioxane, a ketone such as acetone or cyclohexanone, an ester such as ethyl acetate or γ-butyrolactone, a carbonate such as ethylene carbonate or propylene carbonate, an amine such as triethylamine, a nitrogen-containing heterocyclic aromatic compound such as pyridine, a nitrile such as acetonitrile or succinonitrile, an amide such as N,N-dimethylformamide, N,N-dimethylacetamide, or N-methylpyrrolidone, a urea compound such as tetramethylurea, a nitro compound such as nitromethane or nitrobenzene, a sulfur compound such as dimethyl sulfoxide or sulfolane, and a phosphorus compound such as hexamethylphosphoramide or tri-n-butyl phosphate. Among these, two or more kinds thereof may be used in combination.

From the viewpoints of low corrosiveness and satisfactory handleability, a solvent containing, as a main component, an aprotic compound, particularly an aprotic compound having no halogen atom is preferable as the solvent, and the proportion of the aprotic compound in the entire solvent is preferably in a range of 50% by mass to 100% by mass, more preferably in a range of 70% by mass to 100% by mass, and particularly preferably in a range of 90% by mass to 100% by mass. Further, from the viewpoint of easily dissolving the liquid crystal polymer, as the aprotic compound, an amide such as N,N-dimethylformamide, N,N-dimethylacetamide, tetramethylurea, or N-methylpyrrolidone, or an ester such as γ-butyrolactone is preferable, and N,N-dimethylformamide, N,N-dimethylacetamide, or N-methylpyrrolidone is more preferable.

From the viewpoint of easily dissolving the liquid crystal polymer, a solvent containing a compound having a dipole moment of 3 to 5 as a main component is preferable as the solvent, and the proportion of the compound having a dipole moment of 3 to 5 in the entire solvent is preferably in a range of 50% by mass to 100% by mass, more preferably in a range of 70% by mass to 100% by mass, and particularly preferably in a range of 90% by mass to 100% by mass.

It is preferable to use a compound having a dipole moment of 3 to 5 as the aprotic compound.

From the viewpoint of ease removal, a solvent containing, as a main component, a compound having a boiling point of 220° C. or lower at 1 atm is preferable as the solvent, and the proportion of the compound having a boiling point of 220° C. or lower at 1 atm in the entire solvent is preferably in a range of 50% by mass to 100% by mass, more preferably in a range of 70% by mass to 100% by mass, and particularly preferably in a range of 90% by mass to 100% by mass.

It is preferable to use a compound having a boiling point of 220° C. or lower at 1 atm as the aprotic compound.

Further, in a case where the film is produced by the co-casting method, the multilayer coating method, the co-extrusion method, or the likes, a support may be used in the method of producing the film according to the present disclosure. Further, in a case where the metal layer (metal foil) or the like used in the laminate described below is used as the support, the support may be used as it is without being peeled.

Examples of the support include a metal drum, a metal band, a glass plate, a resin film, and a metal foil. Among these, a metal drum, a metal band, or a resin film is preferable.

Examples of the resin film include a polyimide (PI) film, and examples of commercially available products thereof include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

Further, the support may have a surface treatment layer formed on the surface so that the support can be easily peeled off. Hard chrome plating, a fluororesin, or the like can be used for the surface treatment layer.

The average thickness of the resin film support is not particularly limited, but is preferably 25 μm or greater and 75 μm or less and more preferably 50 μm or greater and 75 μm or less.

Further, the method for removing at least a part of the solvent from a cast or applied film-like composition (a casting film or a coating film) is not particularly limited, and a known drying method can be used.

Stretching

The liquid crystal film according to the present disclosure can be obtained by appropriately combining stretching from the viewpoint of controlling the molecular alignment and adjusting the linear expansion coefficient and the mechanical properties. The stretching method is not particularly limited, and a known method can be referred to, and the stretching method may be carried out in a solvent-containing state or in a dry film state. The stretching in the solvent-containing state may be carried out by gripping and stretching the film, by using a self-contractile force of a web due to drying without stretching the film, or by combining these methods. Stretching is particularly effective for the purpose of improving the breaking elongation and the breaking strength in a case where the brittleness of the film is reduced by addition of an inorganic filler or the like.

Laminate

A laminate according to the present disclosure may be a laminate obtained by laminating the film according to the present disclosure, and the laminate includes preferably the film according to the present disclosure and a metal layer or metal wire disposed on at least one surface of the film and more preferably the film according to the present disclosure and a copper layer or copper wire disposed on at least one surface of the film.

Further, the laminate according to the present disclosure includes preferably a metal layer or a metal wire, the film according to the present disclosure, and a metal layer or a metal wire in this order and more preferably a copper layer or a copper wire, the film according to the present disclosure, and a copper layer or a copper wire in this order.

Further, it is preferable that the laminate according to the present disclosure includes the film according to the present disclosure, a copper layer or a copper wire, the film according to the present disclosure, a metal layer or a metal wire, and the film according to the present disclosure in this order. The two films according to the present disclosure used for the laminate may be the same as or different from each other.

The metal layer and the metal wire are not particularly limited and may be known metal layers and metal wires, but for example, a silver layer, a silver wire, a copper layer, or a copper wire is preferable, and a copper layer or a copper wire is more preferable.

Further, it is preferable that the metal layer and the metal wire are metal wires.

Further, the metal in the metal layer and the metal wire is preferably silver or copper and more preferably copper.

Since the film according to the present disclosure can be further cured, for example, after the metal layer or the metal wire is bonded to the film, it is preferable that the laminate according to the present disclosure contains a cured substance obtained by curing the curable compound A, from the viewpoint of durability.

The method of bonding the film according to the present disclosure and the metal layer or the metal wire to each other is not particularly limited, and a known laminating method can be used.

The peel strength between the film and the copper layer is preferably 0.5 kN/m or greater, more preferably 0.7 kN/m or greater, still more preferably in a range of 0.7 kN/m to 2.0 kN/m, and particularly preferably in a range of 0.9 kN/m to 1.5 kN/m.

In the present disclosure, the peel strength between the film and the metal layer (for example, the copper layer) is measured by the following method.

A peeling test piece with a width of 1.0 cm is prepared from the laminate of the film and the metal layer, the film is fixed to a flat plate with double-sided adhesive tape, and the strength (kN/m) in a case of peeling the film off from the metal layer at a rate of 50 mm/min is measured by the 180° method in conformity with JIS C 5016 (1994).

The metal layer is preferably a silver layer or a copper layer and more preferably a copper layer. As the copper layer, a rolled copper foil formed by a rolling method or an electrolytic copper foil formed by an electrolytic method is preferable, and a rolled copper foil is more preferable from the viewpoint of bending resistance.

The average thickness of the metal layer, preferably a copper layer, is not particularly limited, but is preferably in a range of 2 μm to 20 μm, more preferably in a range of 3 μm to 18 μm, and still more preferably in a range of 5 μm to 12 μm. The copper foil may be copper foil with a carrier formed on a support (carrier) so as to be peelable. As the carrier, a known carrier can be used. The average thickness of the carrier is not particularly limited, but is preferably in a range of 10 μm to 100 μm and more preferably in a range of 18 μm to 50 μm.

Further, from the viewpoint of further exhibiting the effects of the present disclosure, it is preferable that the metal layer contains a group that can interact with the film, on the surface of the metal layer on the side in contact with the film. In addition, preferred examples of the group that can interact with the film include combinations of covalently bondable groups, such as an amino group and an epoxy group, and a hydroxy group and an epoxy group.

Among these, from the viewpoints of adhesiveness and ease of performing a treatment, a covalently bondable group is preferable, an amino group or a hydroxy group is more preferable, and an amino group is particularly preferable.

It is also preferable that the metal layer in the laminate according to the present disclosure is processed into, for example, a desired circuit pattern by etching to form a flexible printed circuit board. The etching method is not particularly limited, and a known etching method can be used.

Further, in the laminating step, it is preferable to bond a metal wire.

A laminating method in the laminating step is not particularly limited, and a known laminating method can be used.

The bonding pressure in the laminating step is not particularly limited, but is preferably 0.1 MPa or greater and more preferably 0.2 MPa to 10 MPa.

The bonding temperature in the laminating step can be appropriately selected depending on the film or the like to be used, but is preferably 150° C. or higher, more preferably 280° C. or higher, and particularly preferably 280° C. or higher and 420° C. or lower.

### EXAMPLES

Hereinafter, the present disclosure will be described in more detail with reference to examples. The materials, the used amounts, the ratios, the treatment contents, the treatment procedures, and the like described in the following examples can be appropriately changed without departing from the gist of the present disclosure. Therefore, the scope of the present disclosure is not limited to the following specific examples.

The details of the materials used in the examples and the comparative examples are as follows.

Matrix Material

LC-A: Liquid crystal polymer prepared by production method described below

Production of LC-A

940.9 g (5.0 mol) of 6-hydroxy-2-naphthoic acid, 377.9 g (2.5 mol) of 4-hydroxyacetaminophen, 415.3 g (2.5 mol) of isophthalic acid, and 867.8 g (8.4 mol) of acetic anhydride were added to a reactor provided with a stirrer, a torque meter, a nitrogen gas introduction pipe, a thermometer, and a reflux condenser, the gas inside the reactor was substituted with nitrogen gas, and the mixture was heated from room temperature (23° C.) to 140° C. for 60 minutes while being stirred in a nitrogen gas stream and was refluxed at 140° C. for 3 hours.

Thereafter, the mixture was heated from 150° C. to 300° C. for 5 hours while by-product acetic acid and unreacted acetic anhydride were distilled off and maintained at 300° C. for 30 minutes, and the contents were taken out from the reactor and cooled to room temperature. The obtained solid matter was crushed with a crusher, thereby obtaining powdery liquid crystal polyester (B1). The flow start temperature of the liquid crystal polyester (B1) was 193.3° C.

The liquid crystal polyester (B1) obtained above was heated from room temperature to 160° C. for 2 hours and 20 minutes in a nitrogen atmosphere, further heated from 160° C. to 180° C. for 3 hours and 20 minutes, maintained at 180° C. for 5 hours to carry out solid-phase polymerization, cooled, and crushed with a crusher, thereby obtaining powdery liquid crystal polyester (B2). The flow start temperature of the liquid crystal polyester (B2) was 220° C.

The liquid crystal polyester (B2) obtained above was heated from room temperature (23° C.) to 180° C. for 1 hour and 25 minutes in a nitrogen atmosphere, further heated from 180° C. to 255° C. for 6 hours and 40 minutes, maintained at 255° C. for 5 hours to carry out solid-phase polymerization, and cooled, thereby obtaining powdery liquid crystal polyester (B) (LC-A). The flow start temperature of the liquid crystal polyester (B) was 302° C. Further, the melting point of the liquid crystal polyester (B) was measured using a differential scanning calorimetry device, and the measured value was 311° C.

Particles

A-1: Silica particles (average particle diameter of 400 nm, hexamethyldisilazane treatment)

Compound Forming Region A

R-1 (Compound forming region A on particle surface): Olefin-based pressure sensitive adhesive composition (mixture of acid-modified polyolefin and epoxy resin), loss tangent: 1, elastic modulus: 0.1 GPa

R-2 (Compound forming region A on particle surface): Olefin-based pressure sensitive adhesive composition (mixture of acid-modified polyolefin resin and epoxy resin), loss tangent: 0.3, elastic modulus: 0.2 GPa

R-3 (Compound contained in region A phase-separated from matrix material): styrene-butadiene rubber (SBR), loss tangent: 0.2, elastic modulus: 0.5 GPa

The details of Examples 1 to 4 and Comparative Example 1 are described below.

### Example 1 to 4 and Comparative Example 1

Film Formation

A film was formed according to the following casting.

Single Layer Casting (Solution Film Formation)

Preparation of Polymer Solution

The polymer listed in Table 1 was added to N-methylpyrrolidone, and the mixture was stirred at 140° C. for 4 hours in a nitrogen atmosphere, allowed to pass through a sintered fiber metal filter having a nominal pore diameter of 10 μm, and allowed to pass through a sintered fiber filter having a nominal pore diameter of 10 μm again, thereby obtaining a polymer solution. Separately, the particles listed in Table 1 and the compound forming the region A listed in Table 1 were added to toluene to obtain a dispersion liquid of the particles. The polymer solution and the dispersion liquid of the particles were mixed with each other such that the volume ratio between the polymer and the particles was set as listed in Table 1, thereby obtaining a polymer solution.

Preparation of Single-Sided Copper-Clad Laminated Plate

The obtained polymer solution was sent to a single-layer type casting die and cast onto a treated surface of a copper foil (CF-T4X-SV-12, manufactured by Fukuda Metal Foil & Powder Co., Ltd., average thickness of 12 μm). The solvent was removed from the cast film by drying the solvent at 40° C. for 4 hours, thereby obtaining a laminate (single-sided copper-clad laminated plate) having a copper layer and a polymer film having the thickness listed in Table 1.

Annealing Step

The obtained single-sided copper-clad laminated plate was further heated at the temperature listed in Table 1 in a nitrogen atmosphere, thereby preparing a single-sided copper-clad laminated plate.

The dielectric loss tangent and the breaking elongation of the film were measured using the obtained single-sided copper-clad laminated plate. In addition, the elastic moduli of the polymer and the particles were measured. The measuring method is as follows.

Elastic Modulus and Loss Tangent

A sample for evaluating a cross section is prepared by embedding a film in an ultraviolet curable resin (UV resin) and cutting the film with a microtome. Subsequently, the storage elastic modulus of the matrix material and the storage elastic modulus of the particles at the measurement temperature, and the loss tangent (loss elastic modulus/storage elastic modulus) of the compound contained in the region A at the measurement temperature were calculated by observing the sample in a VE-AFM mode using a scanning probe microscope (SPA400, manufactured by Hitachi High-Tech Science Corporation).

Dielectric Loss Tangent

The dielectric loss tangent was measured by the resonance perturbation method at a frequency of 10 GHz. A 10 GHz cavity resonator (CP531, manufactured by EM labs, Inc.) was connected to a network analyzer (“E8363B”, manufactured by Agilent Technology), and a film sample (width: 2.0 mm×length: 80 mm) was inserted into the cavity resonator, and the dielectric loss tangent of the film was measured based on a change in resonance frequency before and after the insertion in an environment of a temperature of 25° C. and a humidity 60% RH for 96 hours. Further, the copper foil was removed with ferric chloride before the measurement.

Evaluation of Breaking Elongation (Brittleness)

The obtained single-sided copper-clad laminated plate was etched to take out the film, and a film sample having a length of 200 mm (measurement direction) and a width of 10 mm was cut out. The distance between chucks was set to 100 mm.

The breaking elongation was calculated by performing measurement until the sample was broken in an atmosphere of a temperature of 25° C., a humidity of 60% RH, and a tensile rate of 10%/min using a universal tensile tester “STMT50BP” (manufactured by Toyo Baldwin Co., Ltd.). The brittleness of the film is further improved as the value of the breaking elongation increases.

Table 1 shows the measurement results.

TABLE 1

| | Film | | | | | | | | | | | | |
|---|---|---|---|---|---|---|---|---|---|---|---|---|---|
| | Polymer | | | | | | | | | | | | |
| | (matrix material) | | | Particles | | | Region A | | | | Calcining | Breaking | |
| | | Elastic | Amount | | Elastic | Amount | | | Thick- | Thick- | temper- | elon- | Dielectric |
| | | modulus | (parts by | | modulus | (parts by | | Loss | ness | ness | ature | gation | loss |
| | Type | (GPa) | volume) | Type | (GPa) | volume) | Type | tangent | (μm) | (μm) | (° C.) | (%) | tangent |
| Example 1 | LC-A | 3.1 | 50 | A-1 | >10 | 50 | R-1 | 1 | 0.5 | 50 | 300 | 40 | 0.003 |
| Example 2 | LC-A | 3.1 | 50 | A-1 | >10 | 50 | R-2 | 0.3 | 0.5 | 50 | 300 | 33 | 0.003 |
| Example 3 | LC-A | 3.1 | 50 | A-1 | >10 | 50 | R-2 | 0.3 | 1 | 50 | 300 | 38 | 0.003 |
| Example 4 | LC-A | 3.1 | 50 | A-1 | >10 | 50 | R-3 | 0.2 | 2 | 50 | 300 | 43 | 0.003 |
| Comparative | LC-A | 3.1 | 50 | A-1 | >10 | 50 | — | — | 0 | 50 | 300 | 6 | 0.003 |
| example 1 | | | | | | | | | | | | | |

Further, in a phase-separated structure that is a sea (the polymer)-island (the region A and the particle) structure, the thickness of the region A in Example 4 denotes the average thickness obtained by measuring the thickness of the region A (the distance between the polymer and the particle) present in the periphery of the particle in the island structure close to the polymer forming the sea structure using the above-described method and averaging the measured values.

As listed in Table 1, each of the films of Examples 1 to 4 was a film having a greater value of the breaking elongation and further improved brittleness, as compared with the film of Comparative Example 1.

All of documents, patent applications, and technical standards described in the present specification are incorporated into the present specification by reference to approximately the same extent as a case where it is specifically and respectively described that the respective documents, patent applications, and technical standards are incorporated by reference.

What is claimed is:

1. A film, comprising:
a matrix material; and
a particle having an elastic modulus at 25° C. which is higher than an elastic modulus of the matrix material,
wherein the film has a region A at at least a part between the matrix material and the particle, and
the region A comprises a compound having a loss tangent of 0.1 or greater at 25° C.

2. The film according to claim 1,
wherein an elastic modulus of the compound having a loss tangent of 0.1 or greater at 25° C. is 1 GPa or less.

3. The film according to claim 1,
wherein the particle comprises a particle having a surface on which a layer of the region A is provided.

4. The film according to claim 3,
wherein the layer of the region A has an average thickness of 0.01 μm to 10 μm.

5. The film according to claim 1,
wherein a value of a ratio Ep/Em of an elastic modulus Ep of the particle at 25° C. to an elastic modulus Em of the matrix material at 25° C. is 1.2 or greater.

6. The film according to claim 1,
wherein the particle comprises an inorganic particle.

7. The film according to claim 1,
wherein a content of the particle is 10% by volume or greater with respect to a total volume of the film.

8. The film according to claim 1,
wherein the matrix material has a dielectric loss tangent of 0.01 or less.

9. The film according to claim 1,
wherein the matrix material comprises at least one compound selected from the group consisting of a polymer and a monomer.

10. The film according to claim 1,
wherein the matrix material comprises at least one polymer selected from the group consisting of a liquid crystal polymer, a cycloolefin polymer, and a fluorine-based polymer.

11. The film according to claim 1,
wherein the region A comprises at least one selected from the group consisting of polyolefin and styrene-butadiene rubber.

12. A laminate, comprising:
the film according to claim 1; and
a copper layer or copper wire disposed on at least one surface of the film.
